(19) United States
(12) Patent Application Publication
(10) Pub. No.: US 2025/0174583 A1
(43) Pub. Date: May 29, 2025

(54) HIGH FREQUENCY MODULE AND COMMUNICATION DEVICE

(71) Applicant: Murata Manufacturing Co., Ltd., Nagaokakyo-shi (JP)

(72) Inventors: Kazuya OKAMOTO, Nagaokakyo-shi (JP); Takanori UEJIMA, Nagaokakyo-shi (JP)

(73) Assignee: Murata Manufacturing Co., Ltd., Nagaokakyo-shi (JP)

(21) Appl. No.: 18/954,577

(22) Filed: Nov. 21, 2024

(30) Foreign Application Priority Data
Nov. 27, 2023 (JP) 2023-200073

(51) Int. Cl. H01L 23/66; H01L 23/00; H01L 23/29; H01L 23/538; H01L 25/065; H01L 25/16

(52) U.S. Cl. CPC H01L 23/66; H01L 23/295; H01L 23/5386; H01L 24/16; H01L 25/0655; H01L 25/16; H01L 2223/6605; H01L 2224/16237

(57) ABSTRACT

A high frequency module includes a mounting substrate, a first electronic component, and a second electronic component. The mounting substrate includes a first main surface, a second main surface, a first recess portion, and a second recess portion. A first bump of the first electronic component is disposed in the first recess portion. A second bump of the second electronic component is disposed in the second recess portion. The mounting substrate includes a first region in which a plurality of recess portions including the first recess portion and the second recess portion are formed and a second region in which the plurality of the recess portions are not formed. The second region of the mounting substrate is positioned between the first bump of the first electronic component and the second bump of the second electronic component in a plan view in a thickness direction of the mounting substrate.

### CROSS-REFERENCE TO RELATED APPLICATION

The present application claims priority to Japanese Application No. JP2023-200073, filed in Japan on Nov. 27, 2023, the contents of which is incorporated by reference in its entirety.

### BACKGROUND

### 1. Field

The present disclosure generally relates to a high frequency module and a communication device, and more particularly relates to a high frequency module including a plurality of electronic components and a communication device including the high frequency module.

### 2. Description of the Related Art

Japanese Unexamined Patent Application Publication (Translation of PCT Application) No. 2017-515295 describes a passive on-package including a substrate having a recess portion. In the passive on-package described in Japanese Unexamined Patent Application Publication (Translation of PCT Application) No. 2017-515295, a bump is disposed in the recess portion of the substrate.

### SUMMARY

However, in the passive on-package according to the related art described in Japanese Unexamined Patent Application Publication (Translation of PCT Application) No. 2017-515295, it is difficult to achieve both the low profile of the high frequency module and the strength of the mounting substrate in the high frequency module in which the electronic component such as the passive on-package is disposed on the mounting substrate.

The present disclosure has been made in view of the above-described points, and an exemplary embodiment of the present disclosure is to provide a high frequency module and a communication device capable of achieving both the low profile and strength of a mounting substrate.

A high frequency module according to an aspect of the present disclosure includes: a mounting substrate; a first electronic component; and a second electronic component. The mounting substrate includes a first main surface and a second main surface. The first main surface and the second main surface face each other. The first electronic component is disposed on the first main surface of the mounting substrate and includes a first bump. The second electronic component is disposed on the first main surface of the mounting substrate and includes a second bump. The mounting substrate includes a first recess portion and a second recess portion. The first recess portion is formed on the first main surface. The second recess portion is formed on the first main surface and is different from the first recess portion. The first bump is disposed in the first recess portion of the mounting substrate. The second bump is disposed in the second recess portion of the mounting substrate. The mounting substrate includes a first region and a second region. The first region is a region in which a plurality of recess portions including the first recess portion and the second recess portion are formed. The second region is a region in which the plurality of recess portions are not formed. The second region of the mounting substrate is positioned between the first bump of the first electronic component and the second bump of the second electronic component in a plan view in a thickness direction of the mounting substrate.

A communication device according to an aspect of the present disclosure includes the high frequency module and a signal processing circuit. The signal processing circuit is connected to the high frequency module.

With the high frequency module and the communication device according to the aspects of the present disclosure, it is possible to achieve both the low profile of the high frequency module and the strength of the mounting substrate.

### BRIEF DESCRIPTION OF THE DRAWINGS

FIG. 1 is a cross-sectional view of a high frequency module according to Embodiment 1;

FIG. 2 is a plan view of the above high frequency module;

FIG. 3 is a block diagram of a communication device according to Embodiment 1;

FIG. 4 is a plan view of a main part of a mounting substrate of a high frequency module according to Embodiment 2;

FIG. 5A is a cross-sectional view of a main part of a mounting substrate of a high frequency module according to Embodiment 3. FIG. 5B is a cross-sectional view of a main part of a mounting substrate of a high frequency module according to Modification Example 1 of Embodiment 3. FIG. 5C is a cross-sectional view of a main part of a mounting substrate of a high frequency module according to Modification Example 2 of Embodiment 3;

FIG. 6 is a plan view of a main part of a mounting substrate of a high frequency module according to Embodiment 4;

FIG. 7 is a plan view of a main part of a mounting substrate of a high frequency module according to Embodiment 5; and

FIG. 8 is a cross-sectional view of a high frequency module according to Embodiment 6.

### DETAILED DESCRIPTION

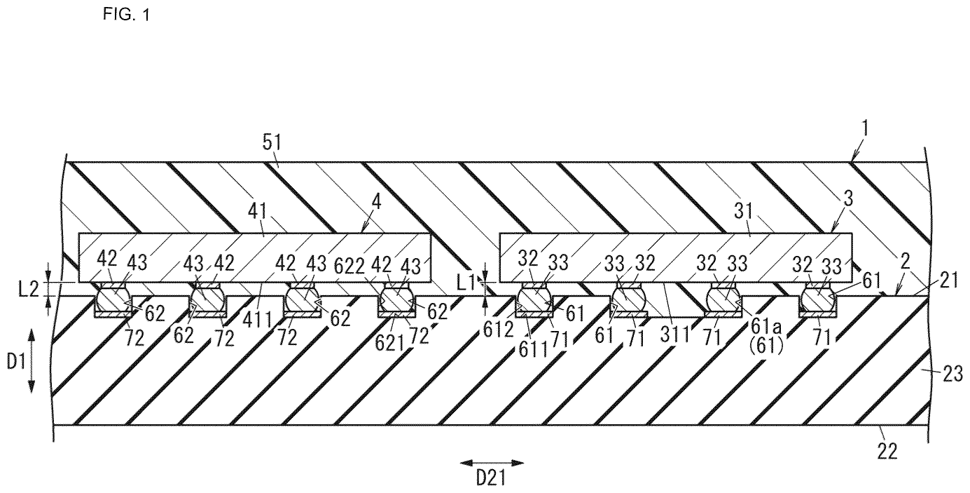

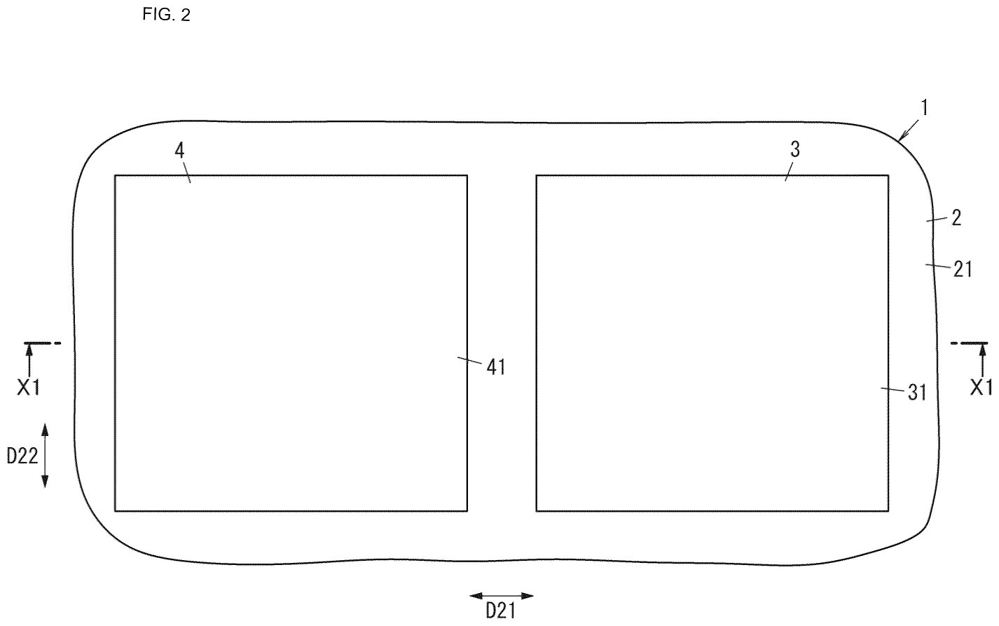

Hereinafter, a high frequency module 1 and a communication device 9 according to Embodiments 1 to 6 will be described with reference to the accompanying drawings. FIGS. 1, 2, and 4 to 8 referred to in the following embodiments and the like are schematic diagrams, and each ratio of a size or a thickness of each component in FIGS. 1, 2, and 4 to 8 does not necessarily reflect an actual dimensional ratio. FIG. 1 is a cross-sectional view taken along the line X1-X1 of FIG. 2.

### Embodiment 1

### (1) HIGH FREQUENCY MODULE

A configuration of the high frequency module 1 according to Embodiment 1 will be described with reference to the drawings.

The high frequency module 1 according to Embodiment 1 includes a mounting substrate 2, a first electronic component 3, a second electronic component 4, and a resin layer 51, as shown in FIG. 1. The mounting substrate 2 includes a first main surface 21 and a second main surface 22. The first main surface 21 and the second main surface 22 face each other. The first electronic component 3 is disposed on the first main surface 21 of the mounting substrate 2 and includes a plurality of first bumps 33. The second electronic component 4 is disposed on the first main surface 21 of the mounting substrate 2 and includes a plurality of second bumps 43. The mounting substrate 2 includes a plurality of first recess portions 61 and a plurality of second recess portions 62. The plurality of first recess portions 61 are formed on the first main surface 21. The plurality of second recess portions 62 are formed on the first main surface 21 and are different from the plurality of first recess portions 61. The first bump 33 is disposed in the first recess portion 61 of the mounting substrate 2. The second bump 43 is disposed in the second recess portion 62 of the mounting substrate 2. The mounting substrate 2 includes a first region and a second region. The first region is a region in which a plurality of recess portions including the first recess portion 61 and the second recess portion 62 are formed. The second region is a region in which a plurality of the recess portions are not formed. The second region of the mounting substrate 2 is positioned between the first bump 33 of the first electronic component 3 and the second bump 43 of the second electronic component 4 in a plan view in a thickness direction D1 of the mounting substrate 2.

In the present specification, the expression “the second region of the mounting substrate 2 is positioned between the first bump 33 of the first electronic component 3 and the second bump 43 of the second electronic component 4 in a plan view in the thickness direction D1 of the mounting substrate 2” means that the second region of the mounting substrate 2 is disposed in a region surrounded by a straight line connecting any point of the first electronic component 3 and any point of the second electronic component 4. In this case, at least a part of the second region of the mounting substrate 2 need only be included in a region surrounded by a straight line connecting any point of the first electronic component 3 and any point of the second electronic component 4.

With the high frequency module 1 according to Embodiment 1, it is possible to achieve both the low profile of the high frequency module 1 and the strength of the mounting substrate 2.

### (2) EACH COMPONENT OF HIGH FREQUENCY MODULE

Hereinafter, each of the components of the high frequency module 1 according to Embodiment 1 will be described with reference to the drawings.

As shown in FIG. 1, the high frequency module 1 according to Embodiment 1 includes the mounting substrate 2, the first electronic component 3, the second electronic component 4, the resin layer 51, and the plurality of external connection terminals.

### (2.1) Mounting Substrate

As shown in FIG. 1, the mounting substrate 2 includes the first main surface 21 and the second main surface 22. The first main surface 21 and the second main surface 22 face each other. More specifically, the first main surface 21 and the second main surface 22 face each other in a thickness direction D1 of the mounting substrate 2. The mounting substrate 2 is a substrate for mounting the plurality of electronic components, and has, for example, a rectangular plate shape. The first main surface 21 and the second main surface 22 are, for example, rectangular. The second main surface 22 faces an external substrate in a case that the high frequency module 1 is provided on the external substrate.

The mounting substrate 2 includes a plurality of dielectric layers 23 and a plurality of conductive layers. The mounting substrate 2 is, for example, a multilayer substrate having a plurality of dielectric layers 23 and a plurality of conductive layers. The plurality of dielectric layers 23 and the plurality of conductive layers are laminated in the thickness direction D1 of the mounting substrate 2.

Each of the plurality of conductive layers includes one or a plurality of conductor portions in one plane orthogonal to the thickness direction D1 of the mounting substrate 2. The plurality of conductive layers are formed in a predetermined pattern determined for each layer. A material of each conductive layer is, for example, copper.

The plurality of conductive layers include a ground layer. The ground layer is a layer set to a ground potential (reference potential), and is provided inside the mounting substrate 2. In a case that the high frequency module 1 is disposed on the external substrate (for example, a motherboard), the ground layer is connected to the ground of the external substrate with the via conductor or the like of the mounting substrate 2 interposed therebetween and is maintained at a ground potential (reference potential).

The mounting substrate 2 is, for example, a low temperature co-fired ceramics (LTCC) substrate. The mounting substrate 2 is not limited to the LTCC substrate, and may be, for example, a printed wiring board, a high temperature co-fired ceramics (HTCC) substrate, or a resin multilayer substrate.

### (2.2) First Electronic Component

As shown in FIGS. 1 and 2, the first electronic component 3 are disposed on the first main surface 21 of the mounting substrate 2. More specifically, the first electronic component 3 is mounted on the first main surface 21 of the mounting substrate 2. The first electronic component 3 is, for example, an amplifier or a filter. The first electronic component 3 is, for example, a power amplifier, a transmission filter, a reception filter, or a low noise amplifier.

The first electronic component 3 includes a main body portion 31, a plurality of electrodes 32, and a plurality of first bumps 33. The first electronic component 3 is disposed on the first main surface 21 of the mounting substrate 2 by connecting the plurality of electrode 32 to a plurality of first electrodes 71 provided on the first main surface 21 of the mounting substrate 2 with the plurality of first bumps 33 interposed therebetween.

The main body portion 31 has a functional unit. The main body portion 31 is disposed on the mounting substrate 2 such that one main surface 311 of the main body portion 31 faces the mounting substrate 2 in the thickness direction D1 of the mounting substrate 2. More specifically, one main surface 311 of the main body portion 31 faces the first main surface 21 of the mounting substrate 2 in a state where the first electronic component 3 is disposed on the mounting substrate 2.

The plurality of electrodes 32 are formed on one main surface 311 of the main body portion 31. The plurality of electrodes 32 are provided, for example, on one main surface 311 of the main body portion 31 at intervals from each other.

The plurality of first bumps 33 are bumps for connecting the plurality of electrodes 32 to the conductive layer of the mounting substrate 2. The plurality of first bumps 33 are disposed on the plurality of electrodes 32. Each of the first bumps 33 is formed in, for example, a circular shape. Each of the first bumps 33 is formed of, for example, solder.

### (2.3) Second Electronic Component

As shown in FIGS. 1 and 2, the second electronic component 4 is disposed on the first main surface 21 of the mounting substrate 2. More specifically, the second electronic component 4 is mounted on the first main surface 21 of the mounting substrate 2. The second electronic component 4 is, for example, an amplifier or a filter. The second electronic component 4 is, for example, a power amplifier, a transmission filter, a reception filter, or a low noise amplifier. The second electronic component 4 is disposed adjacent to the first electronic component 3 in a first direction D21. The first direction D21 is a direction orthogonal to both the thickness direction D1 and a second direction D22 of the mounting substrate 2.

The second electronic component 4 includes a main body portion 41, a plurality of electrodes 42, and a plurality of second bumps 43. The second electronic component 4 is disposed on the first main surface 21 of the mounting substrate 2 by connecting the plurality of electrode 42 to a plurality of second electrodes 72 provided on the first main surface 21 of the mounting substrate 2 with the plurality of second bumps 43 interposed therebetween.

The main body portion 41 has a functional unit. The main body portion 41 is disposed on the mounting substrate 2 such that one main surface 411 of the main body portion 41 faces the mounting substrate 2 in the thickness direction D1 of the mounting substrate 2. More specifically, one main surface 411 of the main body portion 41 faces the first main surface 21 of the mounting substrate 2 in a state where the second electronic component 4 is disposed on the mounting substrate 2.

The plurality of electrodes 42 are formed on one main surface 411 of the main body portion 41. The plurality of electrodes 42 are provided, for example, on one main surface 411 of the main body portion 41 at intervals from each other.

The plurality of second bumps 43 are bumps for connecting the plurality of electrodes 42 to the conductive layer of the mounting substrate 2. The plurality of second bumps 43 are disposed on the plurality of electrodes 42. Each of the second bumps 43 is formed in, for example, a circular shape. Each of the second bumps 43 is formed of, for example, solder.

### (2.4) Arrangement Relationship of Mounting Substrate, First Electronic Component, and Second Electronic Component

As shown in FIG. 1, the mounting substrate 2 includes a plurality of first recess portions 61 and a plurality of second recess portions 62. The plurality of first recess portions 61 are formed on the first main surface 21 of the mounting substrate 2. Each of the plurality of first recess portions 61 includes a bottom surface 611 and a side surface 612. The plurality of second recess portions 62 are formed on the first main surface 21 of the mounting substrate 2. The plurality of second recess portions 62 are recess portions different from the plurality of first recess portions 61. Each of the plurality of second recess portions 62 includes a bottom surface 621 and a side surface 622.

The mounting substrate 2 includes a plurality of first electrodes 71 and a plurality of second electrodes 72. The plurality of first electrodes 71 are disposed in the plurality of first recess portions 61. More specifically, the plurality of first electrodes 71 are disposed on the bottom surfaces 611 of the plurality of first recess portions 61. The plurality of second electrodes 72 are disposed in the plurality of second recess portions 62. More specifically, the plurality of second electrodes 72 are disposed on the bottom surfaces 621 of the plurality of second recess portions 62.

The plurality of first bumps 33 of the first electronic component 3 are disposed in the plurality of first recess portions 61 of the mounting substrate 2. More specifically, in each of the plurality of first bumps 33, the first bump 33 is disposed in the first recess portion 61 such that at least a part of the first bump 33 is accommodated in the first recess portion 61. In the example of FIG. 1, the two first recess portions 61 in the center are integrated with each other to form a first recess portion 61a.

Since the first bump 33 of the first electronic component 3 is disposed in the first recess portion 61 of the mounting substrate 2, the height of the first electronic component 3 from the surface of the first main surface 21 of the mounting substrate 2 on which the recess portions (including the first recess portion 61 and the second recess portion 62) are not formed can be reduced, and thus it is possible to achieve low profile of the high frequency module 1.

The plurality of second bumps 43 of the second electronic component 4 are disposed in the plurality of second recess portions 62 of the mounting substrate 2. More specifically, in each of the plurality of second bumps 43, the second bump 43 is disposed in the second recess portion 62 such that at least a part of the second bump 43 is accommodated in the second recess portion 62.

Since the second bump 43 of the second electronic component 4 is disposed in the second recess portion 62 of the mounting substrate 2, the height of the second electronic component 4 from the surface of the first main surface 21 of the mounting substrate 2 on which the recess portions (including the first recess portion 61 and the second recess portion 62) are not formed can be reduced, and thus it is possible to achieve low profile of the high frequency module 1.

The mounting substrate 2 includes a first region and a second region. The first region is a region in which a plurality of recess portions including the plurality of first recess portions 61 and the plurality of second recess portions 62 are formed. The second region is a region in which a plurality of the recess portions are not formed. The second region of the mounting substrate 2 is positioned between the first bump 33 of the first electronic component 3 and the second bump 43 of the second electronic component 4 in a plan view in a thickness direction D1 of the mounting substrate 2. As a result, the thickness of the mounting substrate 2 between the first recess portion 61 and the second recess portion 62 can be increased, and thus the strength of the mounting substrate 2 can be increased as compared with a case where the recess portion is formed between the first recess portion 61 and the second recess portion 62.

The first bump 33 of the first electronic component 3 is, for example, an RF bump, and the second bump 43 of the second electronic component 4 is, for example, a ground bump. As a result, the RF bump of the first electronic component 3 and the ground bump of the second electronic component 4 are separated from each other by the second region. As a result, it is possible to reduce the short-circuit between the adjacent RF bumps and the ground bump, and thus it is possible to suppress the mounting defect of the high frequency module 1.

The first electronic component 3 and the second electronic component 4 have the main body portions 31 and 41 having a functional unit. The main body portions 31 and 41 of the first electronic component 3 and the second electronic component 4 are positioned outside the mounting substrate 2. As a result, the strength of the mounting substrate 2 can be increased as compared with a case where the recess portions accommodating the main body portions 31 and 41 of the first electronic component 3 and the second electronic component 4 are formed in the mounting substrate 2.

### (2.5) Resin Layer

As shown in FIG. 1, the resin layer 51 is disposed on the first main surface 21 of the mounting substrate 2. The resin layer 51 is in contact with the first main surface 21 of the mounting substrate 2 and covers at least a part of the first electronic component 3 and the second electronic component 4. As a result, the mounting substrate 2, the first electronic component 3, and the second electronic component 4 can be protected.

The resin layer 51 contains a resin and a filler. The resin is, for example, an epoxy resin. In the high frequency module 1, a distance L1 between the main body portion 31 of the first electronic component 3 and the mounting substrate 2 is larger than the diameter of the filler contained in the resin layer 51. As a result, the resin layer 51 intrudes into the periphery of the first bump 33 of the first electronic component 3, and thus it is possible to prevent the solder splash while mounting the high frequency module 1 on the motherboard. As a result, it is possible to improve the connection reliability of the first electronic component 3. In addition, a distance L2 between the main body portion 41 of the second electronic component 4 and the mounting substrate 2 is larger than the diameter of the filler contained in the resin layer 51. As a result, the resin layer 51 intrudes into the periphery of the second bump 43 of the second electronic component 4, and thus it is possible to prevent the solder splash while mounting the high frequency module 1 on the motherboard. As a result, it is possible to improve the connection reliability of the second electronic component 4.

### (2.6) External Connection Terminal

The plurality of external connection terminals are disposed on the second main surface 22 of the mounting substrate 2, for example. The plurality of external connection terminals are terminals for electrically connecting the mounting substrate 2 and the external substrate. The plurality of external connection terminals are arranged on the second main surface 22 of the mounting substrate 2 at intervals from each other.

Each of the plurality of external connection terminals is a flat plate-shaped conductive member. Materials of the plurality of external connection terminals are, for example, metal (for example, copper, copper alloy, or the like).

Each of the external connection terminals is connected to an external connection electrode of the external substrate. In the present specification and the like, the expression “A (for example, an external connection terminal) is connected to B (for example, an external connection electrode of an external substrate)” means not only that A and B are in contact with each other but also that A and B are electrically connected to each other with a conductor electrode, a conductor terminal, a wiring, or another circuit component interposed therebetween. The plurality of the external connection terminals are connected to the external connection electrodes of the external substrate with a connection member (for example, a solder bump) formed of a conductor, for example, interposed therebetween.

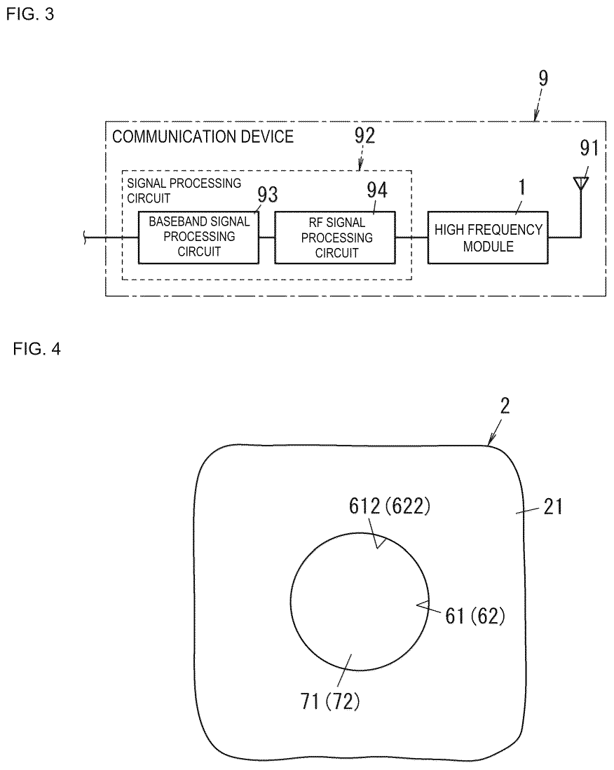

The plurality of external connection terminals include an antenna terminal, a signal input terminal, a signal output terminal, a control terminal, and a ground terminal. The antenna terminal is a terminal to which an antenna 91 (refer to FIG. 3) is connected. The signal input terminal is a terminal for inputting a transmission signal (high frequency signal) from a signal processing circuit 92 (refer to FIG. 3) to the high frequency module 1. The signal output terminal is a terminal for outputting the reception signal (high frequency signal) from the high frequency module 1 to the signal processing circuit 92. The control terminal is a terminal for inputting a control signal from the signal processing circuit 92 to a controller.

### (3) COMMUNICATION DEVICE

As shown in FIG. 3, the communication device 9 includes the high frequency module 1, the antenna 91, and the signal processing circuit 92. The communication device 9 is, for example, a mobile terminal (for example, a smartphone). It should be noted that the communication device 9 is not limited to the mobile terminal, and may be, for example, a wearable terminal (for example, a smart watch).

The high frequency module 1 is configured to amplify a transmission signal (high frequency signal) from the signal processing circuit 92 and output the transmission signal to the antenna 91. The high frequency module 1 is configured to amplify a reception signal (high frequency signal), which is received by the antenna 91, and output the amplified reception signal to the signal processing circuit 92. The high frequency module 1 is controlled by the signal processing circuit 92, for example.

The high frequency module 1 is a module compatible with, for example, a 4G (fourth generation mobile communication) standard and a 5G (fifth generation mobile communication) standard. The 4G standard is, for example, a third generation partnership project (3GPP, registered trademark) long term evolution (LTE, registered trademark) standard. The 5G standard is, for example, 5G new radio (NR). The high frequency module 1 is a module compatible with carrier aggregation and dual connectivity.

In the communication device 9, the high frequency module 1 can be electrically connected to an external substrate. The external substrate corresponds to, for example, a motherboard of a mobile terminal, a communication device, or the like. The fact that the high frequency module 1 can be electrically connected to the external substrate means not only a case where the high frequency module 1 is directly mounted on the external substrate but also a case where the high frequency module 1 is indirectly mounted on the external substrate. The case where the high frequency module 1 is indirectly mounted on the external substrate is a case where the high frequency module 1 is mounted on another high frequency module mounted on the external substrate, or the like.

### (3.1) Antenna

The antenna 91 is connected to an antenna terminal of the high frequency module 1. The antenna 91 has a transmission function of emitting the transmission signal output from the high frequency module 1 as a radio wave, and a reception function of receiving the reception signal from an outside as a radio wave and outputting the reception signal to the high frequency module 1.

### (3.2) Signal Processing Circuit

The signal processing circuit 92 is connected to the high frequency module 1. The signal processing circuit 92 processes a high frequency signal passing through the high frequency module 1. More specifically, the signal processing circuit 92 is configured to perform signal processing on the transmission signal to be output to the high frequency module 1. In addition, the signal processing circuit 92 is configured to perform signal processing on the reception signal received from the high frequency module 1.

The signal processing circuit 92 includes a baseband signal processing circuit 93 and an RF signal processing circuit 94.

For example, the baseband signal processing circuit 93 is a baseband integrated circuit (BBIC).

The baseband signal processing circuit 93 performs predetermined signal processing on a signal from the outside of the signal processing circuit 92. More specifically, the baseband signal processing circuit 93 generates the transmission signal from the baseband signal (for example, the audio signal and the image signal) from the outside of the signal processing circuit 92, and outputs the generated transmission signal to the RF signal processing circuit 94.

The baseband signal processing circuit 93 performs predetermined signal processing on a signal from the RF signal processing circuit 94. More specifically, the baseband signal processing circuit 93 outputs the reception signal received from the RF signal processing circuit 94 to the outside. For example, the reception signal processed by the baseband signal processing circuit 93 is used as an image signal for an image display, or is used as an audio signal for a conversation.

The RF signal processing circuit 94 is, for example, a radio frequency integrated circuit (RFIC) and performs the signal processing on the high frequency signal (the transmission signal and the reception signal).

The RF signal processing circuit 94 performs signal processing on the transmission signal output from the baseband signal processing circuit 93 and outputs the transmission signal on which the signal processing has been performed to the high frequency module 1. Specifically, the RF signal processing circuit 94 performs signal processing, such as up-conversion, on a transmission signal output from the baseband signal processing circuit 93, and outputs the transmission signal on which the signal processing is performed to the transmission path of the high frequency module 1.

The RF signal processing circuit 94 performs signal processing on the reception signal output from the high frequency module 1 and outputs the reception signal on which the signal processing has been performed to the baseband signal processing circuit 93. Specifically, the RF signal processing circuit 94 performs signal processing, such as down-conversion, on the reception signal output from the reception path of the high frequency module 1, and outputs the reception signal on which the signal processing is performed to the baseband signal processing circuit 93.

### (4) EFFECTS

In the high frequency module 1 according to Embodiment 1, the first bump 33 of the first electronic component 3 is disposed in the first recess portion 61 of the mounting substrate 2, the second bump 43 of the second electronic component 4 is disposed in the second recess portion 62 of the mounting substrate 2, and the second region in which the first recess portion 61 and the second recess portion 62 are not formed is positioned between the first bump 33 of the first electronic component 3 and the second bump 43 of the second electronic component 4. Since the first bump 33 of the first electronic component 3 is disposed in the first recess portion 61 of the mounting substrate 2, the height of the first electronic component 3 from the surface of the first main surface 21 of the mounting substrate 2 on which the recess portions (including the first recess portion 61 and the second recess portion 62) are not formed can be reduced. Since the second bump 43 of the second electronic component 4 is disposed in the second recess portion 62 of the mounting substrate 2, the height of the second electronic component 4 from the surface of the first main surface 21 of the mounting substrate 2 on which the recess portions (including the first recess portion 61 and the second recess portion 62) are not formed can be reduced. As a result, it is possible to achieve low profile of the high frequency module 1. Further, the second region of the mounting substrate 2 is positioned between the first bump 33 of the first electronic component 3 and the second bump 43 of the second electronic component 4 in a plan view in the thickness direction D1 of the mounting substrate 2. As a result, the thickness of the mounting substrate 2 between the first recess portion 61 and the second recess portion 62 can be increased, and thus the strength of the mounting substrate 2 can be increased as compared with a case where the recess portion is formed between the first recess portion 61 and the second recess portion 62. As a result, it is possible to achieve both the low profile of the high frequency module 1 and the strength of the mounting substrate 2.

In the high frequency module 1 according to Embodiment 1, the first recess portion 61 is formed in the mounting substrate 2. As a result, the distance between the first electronic component 3 and the wiring conductor or the wiring element built in the mounting substrate 2 can be made shorter than in a case where the first recess portion 61 is not formed.

In the high frequency module 1 according to Embodiment 1, the second recess portion 62 is formed in the mounting substrate 2. As a result, the distance between the second electronic component 4 and the wiring conductor or the wiring element built in the mounting substrate 2 can be made shorter than in a case where the second recess portion 62 is not formed.

In the high frequency module 1 according to Embodiment 1, the first bump 33 of the first electronic component 3 is the RF bump, and the second bump 43 of the second electronic component 4 is the ground bump. As a result, the RF bump of the first electronic component 3 and the ground bump of the second electronic component 4 are separated from each other by the second region. As a result, it is possible to reduce the short-circuit between the adjacent RF bumps and the ground bump, and thus it is possible to suppress the mounting defect of the high frequency module 1.

In the high frequency module 1 according to Embodiment 1, the resin layer 51 that is in contact with the first main surface 21 of the mounting substrate 2 and covers at least a part of the first electronic component 3 and the second electronic component 4 is provided. As a result, the mounting substrate 2, the first electronic component 3, and the second electronic component 4 can be protected.

In the high frequency module 1 according to Embodiment 1, the distance L1 between the main body portion 31 of the first electronic component 3 and the mounting substrate 2 is larger than the diameter of the filler included in the resin layer 51. As a result, the resin layer 51 intrudes into the periphery of the first bump 33 of the first electronic component 3, and thus it is possible to prevent the solder splash while mounting the high frequency module 1 on the motherboard. As a result, it is possible to improve the connection reliability of the first electronic component 3. In addition, the distance L2 between the main body portion 41 of the second electronic component 4 and the mounting substrate 2 is larger than the diameter of the filler included in the resin layer 51. As a result, the resin layer 51 intrudes into the periphery of the second bump 43 of the second electronic component 4, and thus it is possible to prevent the solder splash while mounting the high frequency module 1 on the motherboard. As a result, it is possible to improve the connection reliability of the second electronic component 4.

In the high frequency module 1 according to Embodiment 1, the main body portions 31 and 41 of the first electronic component 3 and the second electronic component 4 are positioned outside the mounting substrate 2. As a result, the strength of the mounting substrate 2 can be increased as compared with a case where the recess portions accommodating the main body portions 31 and 41 of the first electronic component 3 and the second electronic component 4 are formed in the mounting substrate 2.

With the high frequency module 1 according to Embodiment 1, it is possible to achieve low profile of the high frequency module 1 only by performing processing on the mounting substrate 2 even in a case where the first electronic component 3 and the second electronic component 4 having different sizes are disposed on the mounting substrate 2. In other words, the low profile of the high frequency module 1 can be achieved only by performing processing of forming the first recess portion 61 and the second recess portion 62 of the mounting substrate 2.

In the high frequency module 1 according to Embodiment 1, the first bump 33 is disposed in the first recess portion 61, and at least a part of the solder of the first bump 33 fills the first recess portion 61. As a result, the total of the thickness of the mounting substrate 2 and the thickness of the first bump 33 can be increased as compared with a case where the first bump 33 is not disposed in the first recess portion 61, and thus the strength of the mounting substrate 2 can be increased.

In the high frequency module 1 according to Embodiment 1, the second bump 43 is disposed in the second recess portion 62, and at least a part of the solder of the second bump 43 fills the second recess portion 62. As a result, the total of the thickness of the mounting substrate 2 and the thickness of the second bump 43 can be increased as compared with a case where the second bump 43 is not disposed in the second recess portion 62, and thus the strength of the mounting substrate 2 can be increased.

In the high frequency module 1 according to Embodiment 1, the plurality of first recess portions 61 are formed on the mounting substrate 2, and the plurality of first bumps 33 that protrude from one main surface 311 of the main body portion 31 are provided on the first electronic component 3. As a result, it is possible to reduce the non-leveling of the first main surface 21 of the mounting substrate 2 on which the first electronic component 3 is disposed.

In the high frequency module 1 according to Embodiment 1, the plurality of second recess portions 62 are formed on the mounting substrate 2, and the plurality of second bumps 43 that protrude from one main surface 411 of the main body portion 41 are provided on the second electronic component 4. As a result, it is possible to reduce the non-leveling of the first main surface 21 of the mounting substrate 2 on which the second electronic component 4 is disposed.

In the high frequency module 1 according to Embodiment 1, since the first recess portion 61 is provided in the mounting substrate 2, the operation amount of the self-alignment generated when the solder of the first bump 33 is melted can be limited to within the first recess portion 61, and thus the mountability of the first electronic component 3 on the mounting substrate 2 can be improved.

In the high frequency module 1 according to Embodiment 1, since the second recess portion 62 is provided in the mounting substrate 2, the operation amount of the self-alignment generated when the solder of the second bump 43 is melted can be limited to within the second recess portion 62, and thus the mountability of the second electronic component 4 on the mounting substrate 2 can be improved.

In the high frequency module 1 according to Embodiment 1, the first recess portion 61 and the second recess portion 62 are formed on the mounting substrate 2. As a result, compared to a case where the first recess portion 61 and the second recess portion 62 are not formed, the thickness of the mounting substrate 2 can be increased when maintaining the height of the high frequency module 1, and thus the strength of the mounting substrate 2 can be increased.

In the communication device 9 according to Embodiment 1, in the high frequency module 1, the first bump 33 of the first electronic component 3 is disposed in the first recess portion 61 of the mounting substrate 2, the second bump 43 of the second electronic component 4 is disposed in the second recess portion 62 of the mounting substrate 2, and the second region in which the first recess portion 61 and the second recess portion 62 are not formed is provided between the first bump 33 of the first electronic component 3 and the second bump 43 of the second electronic component 4. Accordingly, it is possible to achieve both the low profile of the high frequency module 1 and the strength of the mounting substrate.

### (5) MODIFICATION EXAMPLES

Hereinafter, modification examples of Embodiment 1 will be described.

### (5.1) Modification Example 1

The high frequency module 1 according to Modification Example 1 of Embodiment 1 includes the mounting substrate 2, the first electronic component 3, the second electronic component 4, the resin layer 51, the plurality of external connection terminals, and the shield layer.

The shield layer covers at least a part of the resin layer 51 and the mounting substrate 2. More specifically, the shield layer covers one main surface and an outer peripheral surface of the resin layer 51 and an outer peripheral surface of the mounting substrate 2. One main surface of the resin layer 51 is a main surface on a side opposite to the mounting substrate 2 side in the resin layer 51.

The shield layer has conductivity. More specifically, the shield layer has a multilayer structure in which a plurality of metal layers are laminated. The metal layer includes one or more types of metals. The shield layer is not limited to the above-described multilayer structure, and may be one metal layer.

The shield layer is provided, for example, for the purpose of providing an electromagnetic shield between the inside and the outside of the high frequency module 1. The shield layer is in contact with at least a part of the ground layer of the mounting substrate 2. Therefore, it is possible to set the potential of the shield layer to be equal to the potential of the ground layer.

The shield layer covers at least a part of the main surface of the first electronic component 3 and the main surface of the second electronic component 4. The shield layer may be connected, for example, by coming into contact with the main surface of the first electronic component 3 and the main surface of the second electronic component 4.

### (5.2) Modification Example 2

In the high frequency module 1 according to Modification Example 2 of Embodiment 1, the distance L1 (refer to FIG. 1) between the main body portion 31 of the first electronic component 3 and the mounting substrate 2 is smaller than the diameter of the filler contained in the resin layer 51. In addition, the distance L2 (refer to FIG. 1) between the main body portion 41 of the second electronic component 4 and the mounting substrate 2 is smaller than a diameter of the filler included in the resin layer 51.

With the high frequency module 1 according to Modification Example 2 of Embodiment 1, it is possible to further achieve low profile of the high frequency module 1.

### (5.3) Modification Example 3

In the high frequency module 1 according to Modification Example 3 of Embodiment 1, the resin layer 51 does not contain the filler. The resin layer 51 contains, for example, no filler and contains only a resin.

The high frequency module 1 according to each of the above-described modification examples also has the same effects as the high frequency module 1 according to Embodiment 1.

### Embodiment 2

The high frequency module 1 according to Embodiment 2 is different from the high frequency module 1 (refer to FIG. 1) according to Embodiment 1 in that the side surface 612 of the first recess portion 61 and the side surface 622 of the second recess portion 62 of the mounting substrate 2 are the curved surfaces, as shown in FIG. 4. Regarding the high frequency module 1 according to Embodiment 2, the same components as the high frequency module 1 according to Embodiment 1 are attached with the same reference numerals, and the description thereof will be omitted.

### (1) CONFIGURATION

In the mounting substrate 2 of Embodiment 2, as shown in FIG. 4, the side surface 612 of the first recess portion 61 is a curved surface in a plan view in the thickness direction D1 of the mounting substrate 2.

In the mounting substrate 2 of Embodiment 2, the side surface 622 of the second recess portion 62 is a curved surface in a plan view in the thickness direction D1 of the mounting substrate 2.

Regarding the mounting substrate 2 of Embodiment 2, the same configuration and function as those of the mounting substrate 2 (refer to FIG. 1) of Embodiment 1 will not be described.

### (2) EFFECTS

In the high frequency module 1 according to Embodiment 2, the side surface 612 of the first recess portion 61 is a curved surface in a plan view in the thickness direction D1 of the mounting substrate 2. As a result, the shape of the first recess portion 61 can be made close to the shape of the first bump 33, and thus the self-alignment amount of the solder can be suppressed within the range of the first recess portion 61 in a case that the first electronic component 3 is disposed on the mounting substrate 2. As a result, the mountability of the first electronic component 3 on the mounting substrate 2 can be improved. That is, the mounting variation of the first electronic component 3 can be reduced.

In the high frequency module 1 according to Embodiment 2, the side surface 622 of the second recess portion 62 is a curved surface in a plan view in the thickness direction D1 of the mounting substrate 2. As a result, the shape of the second recess portion 62 can be made close to the shape of the second bump 43, and thus the self-alignment amount of the solder can be suppressed within the range of the second recess portion 62 in a case that the second electronic component 4 is disposed on the mounting substrate 2. As a result, the mountability of the second electronic component 4 on the mounting substrate 2 can be improved. That is, the mounting variation of the second electronic component 4 can be reduced.

### (3) MODIFICATION EXAMPLES

Hereinafter, modification examples of Embodiment 2 will be described.

### (3.1) Modification Example 1

In the high frequency module 1 according to Modification Example 1 of Embodiment 2, among the side surfaces 612 of the plurality of first recess portion 61 and the side surfaces 622 of the plurality of second recess portions 62 of the mounting substrate 2, only the side surfaces 612 of the plurality of first recess portion 61 are the curved surfaces. It should be noted that the side surfaces 612 of some of the plurality of first recess portions 61, but not all of the plurality of first recess portions 61 may be curved surfaces.

In the high frequency module 1 according to Modification Example 1 of Embodiment 2, the mountability of the first electronic component 3 on the mounting substrate 2 can also be improved.

### (3.2) Modification Example 2

In the high frequency module 1 according to Modification Example 2 of Embodiment 2, among the side surfaces 612 of the plurality of first recess portion 61 and the side surfaces 622 of the plurality of second recess portions 62 of the mounting substrate 2, only the side surfaces 622 of the plurality of second recess portion 62 are the curved surfaces. It should be noted that the side surfaces 622 of some of the plurality of second recess portions 62, but not all of the plurality of second recess portions 62 may be curved surfaces.

In the high frequency module 1 according to Modification Example 2 of Embodiment 2, the mountability of the second electronic component 4 on the mounting substrate 2 can also be improved.

In other words, the side surface 612 or 622 of at least one of the plurality of first recess portions 61 and the plurality of second recess portions 62 of the mounting substrate 2 may be a curved surface in a plan view in the thickness direction D1 of the mounting substrate 2.

The high frequency module 1 according to each of the above-described modification examples also has the same effects as the high frequency module 1 according to Embodiment 2.

### Embodiment 3

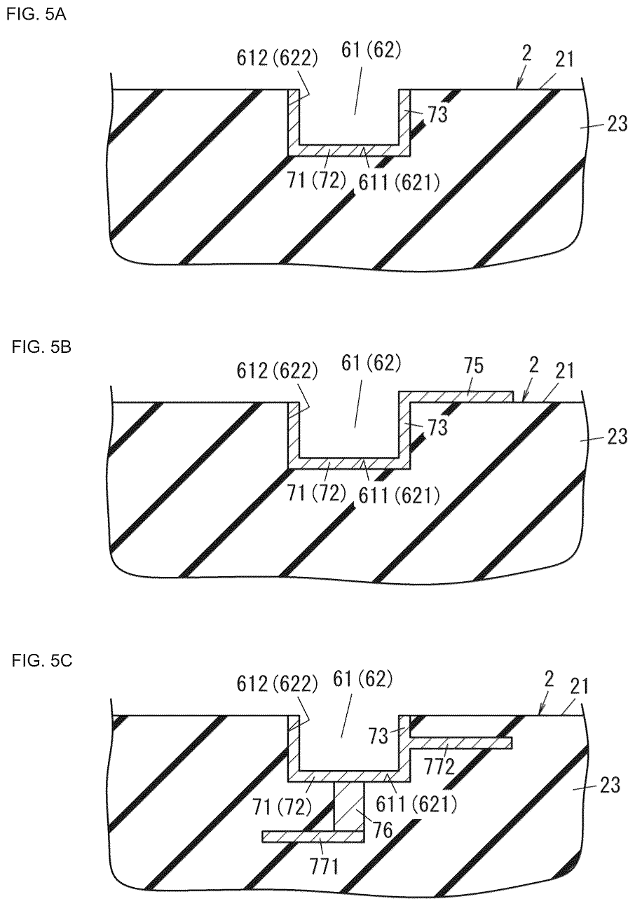

The high frequency module 1 according to Embodiment 3 is different from the high frequency module 1 (refer to FIG. 1) according to Embodiment 1 in that a side surface electrode 73 is formed on the side surface 612 of the plurality of first recess portion 61 and the side surfaces 622 of the plurality of second recess portions 62, as shown in FIG. 5A. Regarding the high frequency module 1 according to Embodiment 3, the same components as the high frequency module 1 according to Embodiment 1 are attached with the same reference numerals, and the description thereof will be omitted.

### (1) Configuration

The mounting substrate 2 according to Embodiment 3 further includes the side surface electrode 73, as shown in FIG. 5A. The side surface electrode 73 is formed on the side surface 612 of the first recess portion 61. In addition, the side surface electrode 73 is formed on the side surface 622 of the second recess portion 62. Regarding the mounting substrate 2 of Embodiment 3, the same configuration and function as those of the mounting substrate 2 (refer to FIG. 1) of Embodiment 1 will not be described.

### (2) Effects

In the high frequency module 1 according to Embodiment 3, the first electrode 71 is formed on the bottom surface 611 of the first recess portion 61, and the side surface electrode 73 is formed on the side surface 612 of the first recess portion 61. As a result, the contact area between the first bump 33 of the first electronic component 3 and the electrodes (the first electrode 71 and the side surface electrode 73) in the first recess portion 61 can be increased, and thus the bonding strength between the first bump 33 of the first electronic component 3 and the electrodes in the first recess portion 61 can be increased. As a result, the mountability of the first electronic component 3 on the mounting substrate 2 can be improved.

In the high frequency module 1 according to Embodiment 3, the second electrode 72 is formed on the bottom surface 621 of the second recess portion 62, and the side surface electrode 73 is formed on the side surface 622 of the second recess portion 62. As a result, the contact area between the second bump 43 of the second electronic component 4 and the electrodes (the second electrode 72 and the side surface electrode 73) in the second recess portion 62 can be increased, and thus the bonding strength between the second bump 43 of the second electronic component 4 and the electrodes in the second recess portion 62 can be increased. As a result, the mountability of the second electronic component 4 on the mounting substrate 2 can be improved.

### (3) MODIFICATION EXAMPLES

Hereinafter, modification examples of Embodiment 3 will be described.

### (3.1) Modification Example 1

In the high frequency module 1 according to Modification Example 1 of Embodiment 3, as shown in FIG. 5B, the mounting substrate 2 includes a wiring pattern conductor 75. The wiring pattern conductor 75 is provided on the first main surface 21 of the mounting substrate 2 to be continuous with the side surface electrode 73.

In the high frequency module 1 according to Modification Example 1 of Embodiment 3, the side surface electrodes 73 are formed on the side surfaces 612 and 622 of at least one of the first recess portion 61 or the second recess portion 62. As a result, the wiring can be extended from the side surfaces 612 and 622 of the recess portions (the first recess portion 61 and the second recess portion 62), and thus the degree of freedom of the wiring can be increased.

### (3.2) Modification Example 2

In the high frequency module 1 according to Modification Example 2 of Embodiment 3, as shown in FIG. 5C, the mounting substrate 2 includes the via conductor 76 and a plurality of wiring pattern conductors 771 and 772.

The via conductor 76 connects the first electrode 71 and the wiring pattern conductor 771. The wiring pattern conductor 772 is connected to the side surface electrode 73. The wiring pattern conductor 772 extends from the side surface electrode 73 in a direction orthogonal to the thickness direction D1 of the mounting substrate 2. The via conductor 76 may be a conductor that connects the second electrode 72 and the wiring pattern conductor 771.

In the high frequency module 1 according to Modification Example 2 of Embodiment 3, the side surface electrodes 73 are formed on the side surface 612 or 622 of at least one of the plurality of first recess portions 61 and the plurality of second recess portions 62. As a result, the wiring can be extended from the side surfaces 612 and 622 of the recess portions (the first recess portion 61 and the second recess portion 62), and thus the degree of freedom of the wiring can be increased.

### (3.3) Modification Example 3

In the high frequency module 1 according to Modification Example 3 of Embodiment 3, the side surface electrodes 73 are formed only on the side surfaces 612 of the plurality of first recess portions 61 among the side surfaces 612 of the plurality of first recess portions 61 and the side surfaces 622 of the plurality of second recess portions 62 of the mounting substrate 2. It should be noted that the side surface electrode 73 may be formed on the side surfaces 612 of some of the plurality of first recess portions 61, but not all of the plurality of first recess portions 61.

In the high frequency module 1 according to Modification Example 3 of Embodiment 3, the degree of freedom of the wiring can also be increased.

### (3.4) Modification Example 4

In the high frequency module 1 according to Modification Example 4 of Embodiment 3, the side surface electrodes 73 are formed only on the side surfaces 622 of the plurality of second recess portions 62 among the side surfaces 612 of the plurality of first recess portions 61 and the side surfaces 622 of the plurality of second recess portions 62 of the mounting substrate 2. It should be noted that the side surface electrode 73 may be formed on the side surfaces 622 of some of the plurality of second recess portions 62, but not all of the plurality of second recess portions 62.

In the high frequency module 1 according to Modification Example 4 of Embodiment 3, the degree of freedom of the wiring can also be increased.

In other words, the mounting substrate 2 need only have the side surface electrode 73 formed on the side surfaces 612 and 622 of at least one of the first recess portion 61 or the second recess portion 62.

The high frequency module 1 according to each of the above-described modification examples also has the same effects as the high frequency module 1 according to Embodiment 3.

### Embodiment 4

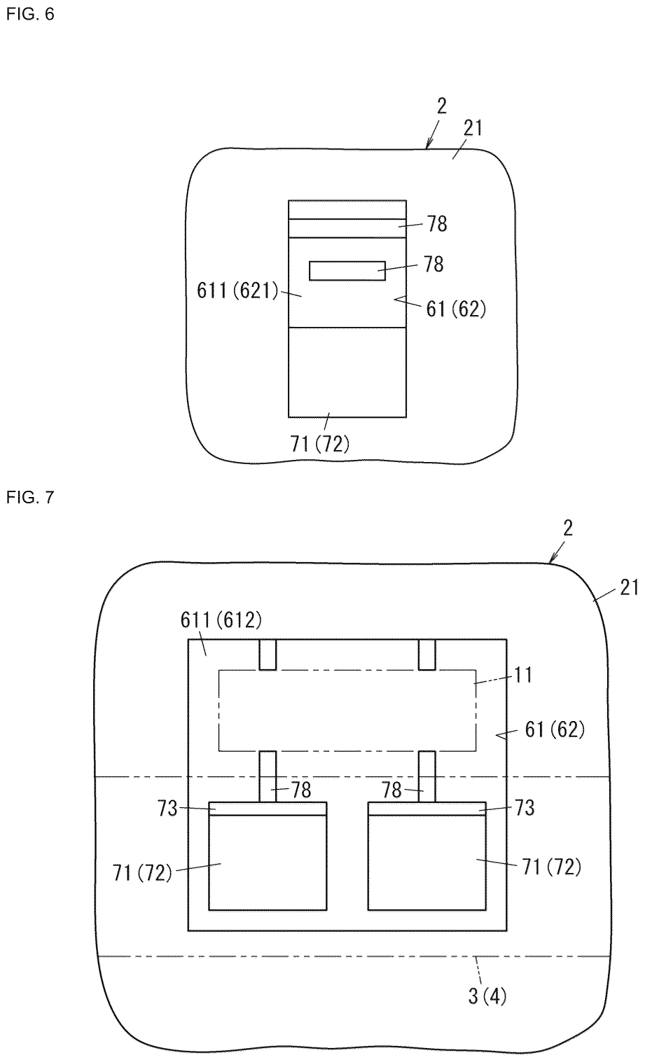

The high frequency module 1 according to Embodiment 4 is different from the high frequency module 1 (refer to FIG. 1) according to Embodiment 1 in that a wiring pattern conductor 78 is formed in the plurality of first recess portions 61 and the plurality of second recess portions 62 of the mounting substrate 2, as shown in FIG. 6. Regarding the high frequency module 1 according to Embodiment 4, the same components as the high frequency module 1 according to Embodiment 1 are attached with the same reference numerals, and the description thereof will be omitted.

### (1) CONFIGURATION

As shown in FIG. 6, the mounting substrate 2 of Embodiment 4 includes the plurality of wiring pattern conductors 78. The wiring pattern conductor 78 is formed on each of the plurality of first recess portions 61. More specifically, the wiring pattern conductor 78 is formed on the bottom surface 611 of each of the plurality of first recess portions 61. In addition, the wiring pattern conductor 78 is formed on each of the plurality of second recess portions 62. More specifically, the wiring pattern conductor 78 is formed on each of the bottom surfaces 621 of the plurality of second recess portions 62. Regarding the mounting substrate 2 of Embodiment 4, the same configuration and function as those of the mounting substrate 2 (refer to FIG. 1) of Embodiment 1 will not be described.

### (2) EFFECTS

In the high frequency module 1 according to Embodiment 4, the wiring pattern conductor 78 is formed in at least one of the plurality of first recess portions 61. As a result, the degree of freedom of the wiring can be increased.

In the high frequency module 1 according to Embodiment 4, the wiring pattern conductor 78 is formed in at least one of the plurality of second recess portions 62. As a result, the degree of freedom of the wiring can be increased.

### (3) MODIFICATION EXAMPLES

Hereinafter, modification examples of Embodiment 4 will be described.

### (3.1) Modification Example 1

In the high frequency module 1 according to Modification Example 1 of Embodiment 4, the wiring pattern conductor 78 is formed only in the plurality of first recess portions 61 among the plurality of first recess portions 61 and the plurality of second recess portions 62 of the mounting substrate 2. The wiring pattern conductor 78 may be formed in some of the plurality of first recess portions 61, but not all of the plurality of first recess portions 61.

In the high frequency module 1 according to Modification Example 1 of Embodiment 4, the degree of freedom of the wiring can also be increased.

### (3.2) Modification Example 2

In the high frequency module 1 according to Modification Example 2 of Embodiment 4, the wiring pattern conductor 78 is formed only in the plurality of second recess portions 62 among the plurality of first recess portions 61 and the plurality of second recess portions 62 of the mounting substrate 2. The wiring pattern conductor 78 may be formed in some of the plurality of second recess portions 62, but not all of the plurality of second recess portions 62.

In the high frequency module 1 according to Modification Example 2 of Embodiment 4, the degree of freedom of the wiring can also be increased.

In other words, the mounting substrate 2 need only have the wiring pattern conductor 78 in at least one of the first recess portion 61 or the second recess portion 62.

### (3.3) Modification Example 3

In the high frequency module 1 according to Modification Example 3 of Embodiment 4, the number of the wiring pattern conductors 78 provided in the plurality of first recess portions 61 is not limited to two, and may be one or three or more. The number of the wiring pattern conductors 78 provided in the plurality of second recess portions 62 is not limited to two, and may be one or three or more.

The high frequency module 1 according to the modification example described above also has the same effects as the high frequency module 1 according to Embodiment 4.

### Embodiment 5

The high frequency module 1 according to Embodiment 5 is different from the high frequency module 1 (refer to FIG. 1) according to Embodiment 1 in that a wound inductor 11 is provided, as shown in FIG. 7. Regarding the high frequency module 1 according to Embodiment 5, the same components as the high frequency module 1 according to Embodiment 1 are attached with the same reference numerals, and the description thereof will be omitted.

### (1) CONFIGURATION

A high frequency module 1 according to Embodiment 5 further includes the wound inductor 11 as shown in FIG. 7. The wound inductor 11 is disposed in at least one of the plurality of first recess portions 61. In addition, the wound inductor 11 is disposed in at least one of the plurality of second recess portions 62.

### (2) EFFECTS

In the high frequency module 1 according to Embodiment 5, the wound inductor 11 is provided in at least one of the plurality of first recess portions 61 or the plurality of second recess portions 62. As a result, the height of the relatively high wound inductor 11 can be reduced, and thus it is possible to further achieve low profile of the high frequency module 1.

### Embodiment 6

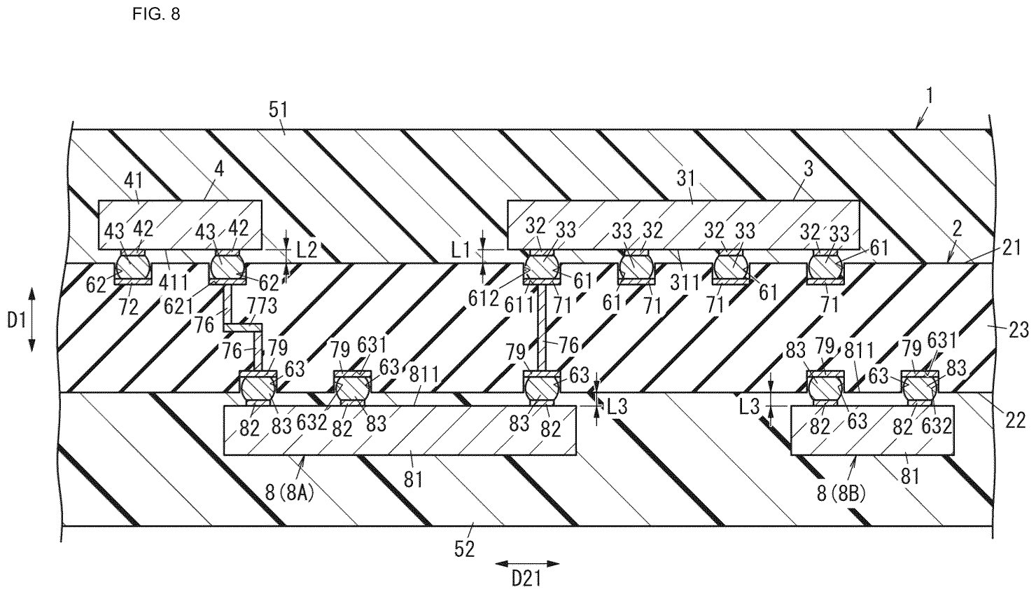

The high frequency module 1 according to Embodiment 6 is different from the high frequency module 1 (refer to FIG. 1) according to Embodiment 1 in that a double-sided mounting structure, as shown in FIG. 8. Regarding the high frequency module 1 according to Embodiment 6, the same components as the high frequency module 1 according to Embodiment 1 are attached with the same reference numerals, and the description thereof will be omitted.

### (1) CONFIGURATION

The high frequency module 1 according to Embodiment 6 includes, as shown in FIG. 8, the mounting substrate 2, the first electronic component 3, the second electronic component 4, a plurality of third electronic components 8, the plurality of resin layers 51 and 52, and the plurality of external connection terminals.

### (1.1) Mounting Substrate

As shown in FIG. 8, the mounting substrate 2 according to Embodiment 6 includes the first main surface 21 and the second main surface 22. The mounting substrate 2 is a double-sided mounting substrate on which the electronic components are mounted on each of the first main surface 21 and the second main surface 22.

### (1.2) Third Electronic Component

As shown in FIG. 8, the plurality of third electronic components 8 are disposed on the second main surface 22 of the mounting substrate 2. The plurality of third electronic components 8 are, for example, an integrated circuit (IC) component. It should be noted that a part of each of the plurality of third electronic components 8 may be disposed on the second main surface 22 of the mounting substrate 2, and the rest of each of the plurality of third electronic components 8 may be incorporated in the mounting substrate 2. In other words, the plurality of third electronic components 8 is positioned further on the second main surface 22 side of the mounting substrate 2 than the first main surface 21, and has at least a part that is mounted on the second main surface 22.

Each of the plurality of third electronic components 8 includes a main body portion 81, a plurality of electrodes 82, and a plurality of third bumps 83. The third electronic component 8 is disposed on the second main surface 22 of the mounting substrate 2 by connecting the plurality of electrode 82 to a plurality of third electrodes 79 provided on the second main surface 22 of the mounting substrate 2 with the plurality of third bumps 83 interposed therebetween.

The main body portion 81 has a functional unit. The main body portion 81 is disposed on the mounting substrate 2 such that one main surface 811 of the main body portion 81 faces the mounting substrate 2 in the thickness direction D1 of the mounting substrate 2. More specifically, one main surface 811 of the main body portion 81 faces the second main surface 22 of the mounting substrate 2 in a state where the third electronic component 8 is disposed on the mounting substrate 2.

The plurality of electrodes 82 are formed on one main surface 811 of the main body portion 81. The plurality of electrodes 82 are provided, for example, on one main surface 811 of the main body portion 81 at intervals from each other.

The plurality of third bumps 83 are bumps for connecting the plurality of electrodes 82 to the conductive layer of the mounting substrate 2. The plurality of third bumps 83 are disposed on the plurality of electrodes 82. Each of the third bumps 83 is formed in, for example, a circular shape. Each of the third bumps 83 is formed of, for example, solder.

In a case where the third electronic component 8 is the IC component, the third electronic component 8 includes, for example, a low noise amplifier and a switch.

The low noise amplifier includes an input terminal and an output terminal. The low noise amplifier amplifies the reception signal input to the input terminal and outputs the amplified reception signal from the output terminal. The input terminal of the low noise amplifier is connected to a common terminal of the switches with an input matching circuit interposed therebetween. The output terminal of the low noise amplifier is connected to a signal output terminal. Therefore, the output terminal of the low noise amplifier is connected to the signal processing circuit 92 with the signal output terminal interposed therebetween.

The switch includes a common terminal and a plurality of selection terminals. The switch is controlled by a controller. The switch switches a connection state between the common terminal and the plurality of selection terminals in response to a control signal from the controller.

Examples of the switch included in the IC component include a first switch, a second switch, and a third switch.

The first switch is an antenna switch connected to an antenna terminal. The common terminal is connected to the antenna terminal. An antenna is connected to the antenna terminal. The selection terminal is connected to, for example, a transmission filter or a reception filter. The first switch is a switch that is capable of connecting at least one or more of the plurality of selection terminals to the common terminal. The first switch is, for example, a switch capable of one-to-one and one-to-many connections.

The second switch is, for example, a band select switch for switching signal paths for a plurality of transmission signals having different communication bands from each other. The second switch includes a common terminal and a plurality of selection terminals. The common terminal is connected to the power amplifier. The selection terminal is connected to the transmission filter. The second switch is a switch that is capable of connecting at least one or more of the plurality of selection terminals to the common terminal. The second switch is, for example, a switch capable of one-to-one and one-to-many connections.

The third switch includes a common terminal and a plurality of selection terminals. The common terminal is connected to the low noise amplifier with the input matching circuit interposed therebetween. The selection terminal is connected to the reception filter. The third switch is a switch that is capable of connecting at least one or more of the plurality of selection terminals to the common terminal. The third switch is, for example, a switch capable of one-to-one and one-to-many connections.

### (1.3) Arrangement Relationship of Mounting Substrate, First Electronic Component, Second Electronic Component, and Third Electronic Component

As shown in FIG. 8, the mounting substrate 2 includes the plurality of first recess portions 61, the plurality of second recess portions 62, and the plurality of third recess portions 63. The plurality of third recess portions 63 are formed on the second main surface 22 of the mounting substrate 2. Each of the plurality of third recess portions 63 includes a bottom surface 631 and a side surface 632. Similarly to the first recess portion 61 and the plurality of second recess portions 62 of Embodiment 1 (refer to FIG. 1), the first recess portion 61 and the plurality of second recess portions 62 are formed on the first main surface 21 of the mounting substrate 2.

The mounting substrate 2 includes the plurality of first electrodes 71, the plurality of second electrodes 72, and the plurality of third electrodes 79. The plurality of third electrodes 79 are disposed on the bottom surfaces 631 of the plurality of third recess portions 63. Similarly to the plurality of first electrodes 71 and the plurality of second electrodes 72 (refer to FIG. 1) of Embodiment 1, the plurality of first electrodes 71 are disposed on the bottom surface 611 of the first recess portion 61, and the plurality of second electrodes 72 are disposed on the bottom surfaces 621 of the plurality of second recess portions 62.

The plurality of third bumps 83 of the plurality of third electronic component 8 are disposed in the plurality of third recess portions 63 of the mounting substrate 2. More specifically, in each of the plurality of third bumps 83, the third bump 83 is disposed in the third recess portion 63 such that at least a part of the third bump 83 is accommodated in the third recess portion 63.

Since the plurality of third bumps 83 of the third electronic component 8 are disposed in the plurality of third recess portions 63 of the mounting substrate 2, it is possible to reduce the height of the third electronic component 8 from the surface of the second main surface 22 of the mounting substrate 2 on which the plurality of third recess portions 63 are not formed, and thus it is possible to achieve low profile of the high frequency module 1.

In the mounting substrate 2 according to Embodiment 6, at least one of the plurality of third recess portions 63 overlaps with the first recess portion 61 in a plan view in the thickness direction D1 of the mounting substrate 2. In the example of FIG. 8, the rightmost third recess portion 63 among the three third recess portions 63 in which the third bumps 83 of the third electronic component 8A are disposed overlaps with the leftmost first recess portion 61 among the four first recess portions 61 in which the first bumps 33 of the first electronic component 3 are disposed in a plan view in the thickness direction D1 of the mounting substrate 2. In addition, the third recess portion 63 on the left side of the two third recess portions 63 in which the third bumps 83 of the third electronic component 8B are disposed overlaps with the rightmost first recess portion 61 among the four first recess portions 61 in which the first bumps 33 of the first electronic component 3 are disposed in a plan view in the thickness direction D1 of the mounting substrate 2.

In addition, in the mounting substrate 2 of Embodiment 6, at least one of the plurality of third recess portions 63 overlaps with the second recess portion 62 in a plan view in the thickness direction D1 of the mounting substrate 2. In the example of FIG. 8, the leftmost third recess portion 63 among the three third recess portions 63 in which the third bumps 83 of the third electronic component 8A are disposed overlaps with the second recess portion 62 on the right side of the two second recess portions 62 in which the second bumps 43 of the second electronic component 4 are disposed in a plan view in the thickness direction D1 of the mounting substrate 2. The second recess portion 62 and the third recess portion 63 are electrically connected to each other by, for example, the plurality of via conductors 76 and a wiring pattern conductors 773.

### (1.4) Resin Layer

As shown in FIG. 8, the resin layer 51 is disposed on the first main surface 21 of the mounting substrate 2. The resin layer 51 is in contact with the first main surface 21 of the mounting substrate 2 and covers at least a part of the first electronic component 3 and the second electronic component 4. As a result, the mounting substrate 2, the first electronic component 3, and the second electronic component 4 can be protected.

The resin layer 51 contains a resin and a filler. The resin is, for example, an epoxy resin. In the high frequency module 1, the distance L1 between the main body portion 31 of the first electronic component 3 and the mounting substrate 2 is larger than the diameter of the filler contained in the resin layer 51. As a result, the resin layer 51 intrudes into the periphery of the first bump 33 of the first electronic component 3, and thus it is possible to prevent the solder splash while mounting the high frequency module 1 on the motherboard. As a result, it is possible to improve the connection reliability of the first electronic component 3. In addition, the distance L2 between the main body portion 41 of the second electronic component 4 and the mounting substrate 2 is larger than the diameter of the filler contained in the resin layer 51. As a result, the resin layer 51 intrudes into the periphery of the second bump 43 of the second electronic component 4, and thus it is possible to prevent the solder splash while mounting the high frequency module 1 on the motherboard. As a result, it is possible to improve the connection reliability of the second electronic component 4.

As shown in FIG. 8, the resin layer 52 is disposed on the second main surface 22 of the mounting substrate 2. The resin layer 52 is in contact with the second main surface 22 of the mounting substrate 2 and covers at least a part of the plurality of third electronic components 8. As a result, the mounting substrate 2 and the plurality of third electronic components 8 can be protected.

The resin layer 52 contains a resin and a filler. The resin is, for example, an epoxy resin. In the high frequency module 1, a distance L3 between the main body portion 81 of the third electronic component 8 and the mounting substrate 2 is larger than the diameter of the filler contained in the resin layer 52. As a result, the resin layer 52 intrudes into the periphery of the third bump 83 of the third electronic component 8, and thus it is possible to prevent the solder splash while mounting the high frequency module 1 on the motherboard. As a result, it is possible to improve the connection reliability of the third electronic component 8.

### (1.5) External Connection Terminal

The plurality of external connection terminals are disposed on the second main surface 22 of the mounting substrate 2, for example. The plurality of external connection terminals are arranged on the second main surface 22 of the mounting substrate 2 at intervals from each other.

Each of the plurality of external connection terminals is a columnar (for example, cylindrical) conductive member. Materials of the plurality of external connection terminals are, for example, metal (for example, copper, copper alloy, or the like). The tip end portion of each of the plurality of external connection terminals may include, for example, a gold plating layer.

### (2) EFFECTS

In a high frequency module 1 according to Embodiment 6, the third electronic components 8A and 8B are disposed on the second main surface 22 of the mounting substrate 2. As a result, the mounting efficiency of the high frequency module 1 can be enhanced.

In the high frequency module 1 according to Embodiment 6, the third bump 83 of the third electronic component 8 is disposed in the third recess portion 63 of the mounting substrate 2. As a result, since the recess portions (the first recess portion 61, the second recess portion 62, and the third recess portion 63) are formed on both surfaces on the first main surface 21 side and the second main surface 22 side of the mounting substrate 2, and the bumps (the first bump 33, the second bump 43, and the third bump 83) are disposed in the recess portions, it is possible to further achieve the low profile of the high frequency module 1.

In the high frequency module 1 according to Embodiment 6, the first recess portion 61, the second recess portion 62, and the third recess portion 63 are formed on the mounting substrate 2. As a result, the distance between the bumps (the first bump 33 and the second bump 43) of the electronic components (the first electronic component 3 and the second electronic component 4) and the third bump 83 of the third electronic component 8 can be made shorter than in a case where the first recess portion 61, the second recess portion 62, and the third recess portion 63 are not formed, and thus the wiring length can be made shorter. As a result, it is possible to reduce the loss of the wiring.

In the high frequency module 1 according to Embodiment 6, the third recess portion 63 overlaps with at least one of the first recess portion 61 or the second recess portion 62 in the thickness direction D1 of the mounting substrate 2. As a result, the distance between the bumps (the first bump 33 and the second bump 43) of the electronic components (the first electronic component 3 and the second electronic component 4) and the third bump 83 of the third electronic component 8 can be further made shorter. As a result, it is possible to further reduce the loss of the wiring.

In the high frequency module 1 according to Embodiment 6, the first recess portion 61, the second recess portion 62, and the third recess portion 63 are formed on the mounting substrate 2. As a result, the thickness of the mounting substrate 2 can be increased when the height of the high frequency module 1 is maintained as compared with the case where the first recess portion 61, the second recess portion 62, and the third recess portion 63 are not formed in the mounting substrate 2, and thus the strength of the mounting substrate 2 can be increased.

### (3) MODIFICATION EXAMPLES

Hereinafter, modification examples of Embodiment 6 will be described.

### (3.1) Modification Example 1

The high frequency module 1 according to Modification Example 1 of Embodiment 6 includes the mounting substrate 2, the first electronic component 3, the second electronic component 4, the plurality of third electronic components 8, the plurality of resin layers 51 and 52, the plurality of external connection terminals, and the shield layer.

The shield layer covers at least a part of the resin layers 51 and 52 and the mounting substrate 2. More specifically, the shield layer covers one main surface and an outer peripheral surface of the resin layer 51, an outer peripheral surface of the mounting substrate 2, and an outer peripheral surface of the resin layer 52. One main surface of the resin layer 51 is a main surface on a side opposite to the mounting substrate 2 side in the resin layer 51. Regarding the shield layer of Modification Example 1 of Embodiment 6, the same configuration and function as those of the shield layer of Modification Example 1 of Embodiment 1 will not be described.

### (3.2) Modification Example 2

In the high frequency module 1 according to Modification Example 2 of Embodiment 6, the third electronic component 8 is not an IC component including the low noise amplifier and the switch, but is another component other than the IC component. The third electronic component 8 may be, for example, only a low noise amplifier or only a switch.

The high frequency module 1 according to each of the above-described modification examples also has the same effects as the high frequency module 1 according to Embodiment 6.

The embodiments and the modification examples described above are merely a part of various embodiments and modification examples of the present disclosure. In addition, in the embodiment and the modification example, various changes can be made according to the design or the like as long as the exemplary embodiments of the present disclosure can be achieved.

### Aspects

The following aspects are disclosed in the present specification.

A high frequency module (1) according to a first aspect includes: a mounting substrate (2); a first electronic component (3); and a second electronic component (4). The mounting substrate (2) includes a first main surface (21) and a second main surface (22). The first main surface (21) and the second main surface (22) face each other. The first electronic component (3) is disposed on the first main surface (21) of the mounting substrate (2) and includes a first bump (33). The second electronic component (4) is disposed on the first main surface (21) of the mounting substrate (2) and includes a second bump (43). The mounting substrate (2) includes a first recess portion (61) and a second recess portion (62). The first recess portion (61) is formed on the first main surface (21). The second recess portion (62) is formed on the first main surface (21) and is different from the first recess portion (61). The first bump (33) is disposed in the first recess portion (61) of the mounting substrate (2). The second bump (43) is disposed in the second recess portion (62) of the mounting substrate (2). The mounting substrate (2) includes a first region and a second region. The first region is a region in which a plurality of recess portions including the first recess portion 61 and the second recess portion 62 are formed. The second region is a region in which a plurality of the recess portions are not formed. The second region of the mounting substrate (2) is positioned between the first bump (33) of the first electronic component (3) and the second bump (43) of the second electronic component (4) in a plan view in the thickness direction (D1) of the mounting substrate (2).

With the high frequency module (1) according to the first aspect, it is possible to achieve both the low profile of the high frequency module (1) and the strength of the mounting substrate (2).

With the high frequency module (1) according to the first aspect, the distance between the first electronic component (3) and the wiring conductor or the wiring element built in the mounting substrate (2) can be made shorter than in a case where the first recess portion (61) is not formed.

In the high frequency module (1) according to the second aspect, in the first aspect, the first bump (33) is an RF bump. The second bump (43) is a ground bump.

With the high frequency module (1) according to the second aspect, the RF bump of the first electronic component (3) and the ground bump of the second electronic component (4) are separated from each other by the second region. As a result, it is possible to reduce the short-circuit between the adjacent RF bumps and the ground bump, and thus it is possible to suppress the mounting defect of the high frequency module (1).

In the high frequency module (1) according to a third aspect, in the first or second aspect, a side surface (612, 622) of at least one of the first recess portion (61) or the second recess portion (62) of the mounting substrate (2) is a curved surface in the plan view in the thickness direction (D1) of the mounting substrate (2).

With the high frequency module (1) according to the third aspect, the shape of at least one of the first recess portion (61) or the second recess portion (62) can be made close to the shape of the bump (the first bump 33 and the second bump 43), and thus, in a case that the electronic components (the first electronic component 3 and the second electronic component 4) are disposed on the mounting substrate (2), the self-alignment amount of the solder can be suppressed within the range of the recess portions (the first recess portion 61 and the second recess portion 62). As a result, the mountability of the electronic component on the mounting substrate (2) can be improved. That is, the mounting variation of the electronic component can be reduced.

In the high frequency module (1) according to a fourth aspect, in any one of the first to third aspects, the mounting substrate (2) includes the side surface electrode (73). The side surface electrode (73) is formed on a side surface (612, 622) of at least one of the first recess portion (61) or the second recess portion (62).

With the high frequency module (1) according to the fourth aspect, the contact area between the bumps (the first bump 33 and the second bump 43) of the electronic components (the first electronic component 3 and the second electronic component 4) and the electrodes in the recess portions (the first recess portion 61 and the second recess portion 62) can be increased, and thus the bonding strength between the bumps of the electronic components and the electrodes in the recess portions can be increased. As a result, the mountability of the electronic component on the mounting substrate (2) can be improved.

With the high frequency module (1) according to the fourth aspect, the wiring can be extended from the side surfaces (612, 622) of the recess portions (the first recess portion 61 and the second recess portion 62), and thus the degree of freedom of the wiring can be increased.

In the high frequency module (1) according to the fifth aspect, in any one of the first to fourth aspects, the mounting substrate (2) includes the wiring pattern conductor (78). The wiring pattern conductor (78) is formed in at least one of the first recess portion (61) and the second recess portion (62).

With the high frequency module (1) according to the fifth aspect, the degree of freedom of the wiring can be increased.

In any one of the first to fifth aspects, the high frequency module (1) according to a sixth aspect further includes a wound inductor (11). The wound inductor (11) is disposed in at least one of the first recess portion (61) or the second recess portion (62).

According to the high frequency module (1) according to the sixth aspect, the height of the relatively high wound inductor (11) can be reduced, and thus the low profile of the high frequency module (1) can be further achieved.

In any one of the first to sixth aspects, the high frequency module (1) according to a seventh aspect further includes a third electronic component (8). The third electronic component (8) is disposed on the second main surface (22) of the mounting substrate (2) and includes a third bump (83).

With the high frequency module (1) according to the seventh aspect, the mounting efficiency of the high frequency module (1) can be enhanced.

In the high frequency module (1) according to an eighth aspect, in the seventh aspect, the mounting substrate (2) further includes a third recess portion (63). The third recess portion (63) is formed on the second main surface (22). The third bump (83) of the third electronic component (8) is disposed in the third recess portion (63) of the mounting substrate (2).

With the high frequency module (1) according to the eighth aspect, since the recess portions (the first recess portion 61, the second recess portion 62, and the third recess portion 63) are formed on both surfaces on the first main surface (21) side and the second main surface (22) side of the mounting substrate (2), the bumps (the first bump 33, the second bump 43, and the third bump 83) are disposed in the recess portions, and thus it is possible to further achieve low profile of the high frequency module (1).

With the high frequency module (1) according to the eighth aspect, the distance between the bumps (first bump 33 and second bump 43) of the electronic components (first electronic component 3 and second electronic component 4) and the third bump (83) of the third electronic component (8) can be made shorter than in a case where the first recess portion (61), the second recess portion (62), and the third recess portion (63) are not formed, and thus the wiring length can be made shorter. As a result, it is possible to reduce the loss of the wiring.

In the high frequency module (1) according to a ninth aspect, in the eighth aspect, the third recess portion (63) of the mounting substrate (2) overlaps with at least one of the first recess portion (61) or the second recess portion (62) of the mounting substrate (2) in the plan view in the thickness direction (D1) of the mounting substrate (2).

With the high frequency module (1) according to the ninth aspect, the distance between the bumps (the first bump 33 and the second bump 43) of the electronic components (the first electronic component 3 and the second electronic component 4) and the third bump (83) of the third electronic component (8) can be further made shorter. As a result, it is possible to further reduce the loss of the wiring.

In any one of the first to ninth aspects, the high frequency module (1) according to a tenth aspect further includes a resin layer (51). The resin layer (51) is in contact with the first main surface (21) of the mounting substrate (2) and covers at least a part of the first electronic component (3) and the second electronic component (4).

With the high frequency module (1) according to the tenth aspect, the mounting substrate (2), the first electronic component (3), and the second electronic component (4) can be protected.

In the high frequency module (1) according to an eleventh aspect, in the tenth aspect, the resin layer (51) contains a filler. A distance (L1) between the first electronic component (3) and the mounting substrate (2) is larger than the diameter of the filler contained in the resin layer (51).

With the high frequency module (1) according to the eleventh aspect, the resin layer (51) intrudes into the periphery of the first bump (33) of the first electronic component (3), it is possible to prevent the solder splash while mounting the high frequency module (1) on the motherboard. As a result, it is possible to improve the connection reliability of the first electronic component (3).

In the high frequency module (1) according to a twelfth aspect, in the tenth aspect, the resin layer (51) contains a filler. A distance (L1) between the first electronic component (3) and the mounting substrate (2) is smaller than a diameter of the filler contained in the resin layer (51).

With the high frequency module (1) according to the twelfth aspect, it is possible to further achieve low profile of the high frequency module (1).

In the high frequency module (1) according to a thirteenth aspect, in any one of the first to twelfth aspects, the first electronic component (3) and the second electronic component (4) further include the main body portions (31, 41) having a functional unit. The main body portions (31, 41) of the first electronic component (3) and the second electronic component (4) are positioned outside the mounting substrate (2).

With the high frequency module (1) according to the thirteenth aspect, the strength of the mounting substrate (2) can be enhanced as compared with a case where the recess portions accommodating the main body portions (31, 41) of the first electronic component (3) and the second electronic component (4) are formed in the mounting substrate (2).

A communication device (9) according to the fourteenth aspect includes the high frequency module (1) according to any one of the first to thirteenth aspects, and a signal processing circuit (92). The signal processing circuit (92) is connected to the high frequency module (1).

With the communication device (9) according to the fourteenth aspect, in the high frequency module (1), it is possible to achieve both the low profile of the high frequency module (1) and the strength of the mounting substrate (2).

What is claimed is:

1. A high frequency module comprising:
a mounting substrate including a first main surface and a second main surface that face each other;
a first electronic component that is disposed on the first main surface of the mounting substrate and includes a first bump, wherein the first electronic component is a first amplifier or a first filter; and
a second electronic component that is disposed on the first main surface of the mounting substrate and includes a second bump, wherein the second electronic component is a second amplifier or a second filter, wherein
the mounting substrate includes
a first recess portion that is formed on the first main surface and a second recess portion that is formed on the first main surface and is different from the first recess portion,
the first bump is disposed in the first recess portion of the mounting substrate,
the second bump is disposed in the second recess portion of the mounting substrate,
the mounting substrate includes
a first region in which a plurality of recess portions including the first recess portion and the second recess portion are formed and a second region in which the plurality of recess portions are not formed, and
the second region of the mounting substrate is positioned between the first bump of the first electronic component and the second bump of the second electronic component in a plan view in a thickness direction of the mounting substrate.

2. The high frequency module according to claim 1, wherein
the first bump is a radio frequency (RF) bump, and
the second bump is a ground bump.

3. The high frequency module according to claim 1, wherein
a side surface of at least one of the first recess portion or the second recess portion of the mounting substrate is a curved surface in the plan view in the thickness direction of the mounting substrate.

4. The high frequency module according to claim 1, wherein
the mounting substrate includes a side surface electrode formed on a side surface of at least one of the first recess portion or the second recess portion.

5. The high frequency module according to claim 1, wherein
the mounting substrate includes a wiring pattern conductor formed in at least one of the first recess portion and the second recess portion.

6. The high frequency module according to claim 1, further comprising:
a wound inductor that is disposed in at least one of the first recess portion or the second recess portion.

7. The high frequency module according to claim 1, further comprising:
a third electronic component that is disposed on the second main surface of the mounting substrate and includes a third bump.

8. The high frequency module according to claim 7, wherein
the mounting substrate further includes a third recess portion formed on the second main surface, and
the third bump of the third electronic component is disposed in the third recess portion of the mounting substrate.

9. The high frequency module according to claim 8, wherein
the third recess portion of the mounting substrate overlaps with at least one of the first recess portion or the second recess portion of the mounting substrate in the plan view in the thickness direction of the mounting substrate.

10. The high frequency module according to claim 1, further comprising:
a resin layer that is in contact with the first main surface of the mounting substrate and covers at least a part of the first electronic component and the second electronic component.

11. The high frequency module according to claim 10, wherein
the resin layer contains a filler, and
a distance between the first electronic component and the mounting substrate is larger than a diameter of the filler contained in the resin layer.

12. The high frequency module according to claim 10, wherein
the resin layer contains a filler, and
a distance between the first electronic component and the mounting substrate is smaller than a diameter of the filler contained in the resin layer.

13. The high frequency module according to claim 1, wherein
the first electronic component and the second electronic component further include a main body portion having a functional unit, and
the main body portions of the first electronic component and the second electronic component are positioned outside the mounting substrate.

14. A communication device comprising:
a high frequency module including
a mounting substrate including a first main surface and a second main surface that face each other;
a first electronic component that is disposed on the first main surface of the mounting substrate and includes a first bump, wherein the first electronic component is a first amplifier or a first filter; and
a second electronic component that is disposed on the first main surface of the mounting substrate and includes a second bump, wherein the second electronic component is a second amplifier or a second filter, wherein
the mounting substrate includes
a first recess portion that is formed on the first main surface and a second recess portion that is formed on the first main surface and is different from the first recess portion,
the first bump is disposed in the first recess portion of the mounting substrate,
the second bump is disposed in the second recess portion of the mounting substrate,
the mounting substrate includes
a first region in which a plurality of recess portions including the first recess portion and the second recess portion are formed and a second region in which the plurality of recess portions are not formed, and
the second region of the mounting substrate is positioned between the first bump of the first electronic component and the second bump of the second electronic component in a plan view in a thickness direction of the mounting substrate; and
a signal processing circuit connected to the high frequency module.

15. The communication device of claim 14, wherein
the first bump is a radio frequency (RF) bump, and
the second bump is a ground bump.

16. The communication device of claim 14, wherein
a side surface of at least one of the first recess portion or the second recess portion of the mounting substrate is a curved surface in the plan view in the thickness direction of the mounting substrate.

17. The communication device of claim 14, wherein
the mounting substrate includes a side surface electrode formed on a side surface of at least one of the first recess portion or the second recess portion.

18. The communication device of claim 14, wherein
the mounting substrate includes a wiring pattern conductor formed in at least one of the first recess portion and the second recess portion.

19. The communication device of claim 14, wherein
a wound inductor that is disposed in at least one of the first recess portion or the second recess portion.

20. The communication device of claim 14, further comprising:
a third electronic component that is disposed on the second main surface of the mounting substrate and includes a third bump.
